(19) United States
(12) Patent Application Publication
(10) Pub. No.: US 2012/0258581 A1
(43) Pub. Date: Oct. 11, 2012

(54) MOCVD FABRICATION OF GROUP III-NITRIDE MATERIALS USING IN-SITU GENERATED HYDRAZINE OR FRAGMENTS THERE FROM

(75) Inventors: Karl Brown, Santa Clara, CA (US); Kevin Griffin, Livermore, CA (US); David Bour, Cupertino, CA (US); Olga Kryliouk, Sunnyvale, CA (US)

(73) Assignee: APPLIED MATERIALS, INC., Santa Clara, CA (US)

(21) Appl. No.: 13/413,014

(22) Filed: Mar. 6, 2012

Related U.S. Application Data
(60) Provisional application No. 61/451,016, filed on Mar. 9, 2011.

(51) Int. Cl. H01L 21/205; C23C 16/50; C23C 16/48; C23C 16/44

(52) U.S. Cl. 438/478; 118/715; 118/723 R; 257/E21.108

(57) ABSTRACT

The metal-organic chemical vapor deposition (MOCVD) fabrication of group III-nitride materials using in-situ generated hydrazine or fragments there from is described. For example, a method of fabricating a group III-nitride material includes forming hydrazine in an in-situ process. The hydrazine, or fragments there from, is reacted with a group III precursor in a metal-organic chemical vapor deposition (MOCVD) chamber. From the reacting, a group III-nitride layer is formed above a substrate.

### CROSS-REFERENCE TO RELATED APPLICATIONS

This application claims the benefit of U.S. Provisional Application No. 61/451,016, filed Mar. 9, 2011, the entire contents of which are hereby incorporated by reference herein.

### BACKGROUND

1) Field

Embodiments of the present invention pertain to the field of group III-nitride materials and, in particular, to the metal-organic chemical vapor deposition (MOCVD) fabrication of group III-nitride materials using in-situ generated hydrazine or fragments there from.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

One or more embodiments of the present invention are directed to metal-organic chemical vapor deposition (MOCVD) fabrication of group III-nitride materials using in-situ generated hydrazine or fragments there from.

In an embodiment, a method of fabricating a group III-nitride material includes forming hydrazine in an in-situ process. The hydrazine, or fragments there from, is reacted with a group III precursor in a metal-organic chemical vapor deposition (MOCVD) chamber. From the reacting, a group III-nitride layer is formed above a substrate.

In another embodiment, a process tool for fabricating a group III-nitride material includes means to form hydrazine in an in-situ process. The process tool also includes a metal-organic chemical vapor deposition (MOCVD) chamber for reacting the hydrazine, or fragments there from, with a group III precursor.

### BRIEF DESCRIPTION OF THE DRAWINGS

FIG. 1A illustrates different representations of the molecule hydrazine (N₂H₄).

FIG. 1B illustrates a collection of possible radical, cation, and anion fragments of hydrazine suitable for delivery of nitrogen to a group III precursor in the formation of a group III-nitride material layer, in accordance with an embodiment of the present invention.

FIG. 2 is a Flowchart representing operations in a method of fabricating a group III-nitride material, in accordance with an embodiment of the present invention.

FIG. 3 includes three SIMS depth profile plots for fabricated InGaN at different growth temperatures, in accordance with an embodiment of the present invention.

FIG. 4 is a schematic cross-sectional view of an MOCVD chamber suitable for the fabrication of group III-nitride materials using in-situ generated hydrazine or fragments there from, in accordance with an embodiment of the present invention.

FIG. 5 illustrates a system suitable for fabrication of group III-nitride materials using in-situ generated hydrazine or fragments there from, in accordance with an embodiment of the present invention.

FIG. 6 illustrates a cross-sectional view of a gallium nitride (GaN)-based light-emitting diode (LED), in accordance with an embodiment of the present invention.

### DETAILED DESCRIPTION

The metal-organic chemical vapor deposition (MOCVD) fabrication of group III-nitride materials using in-situ generated hydrazine or fragments there from is described. In the following description, numerous specific details are set forth, such as MOCVD chamber configurations and material regimes, in order to provide a thorough understanding of embodiments of the present invention. It will be apparent to one skilled in the art that embodiments of the present invention may be practiced without these specific details. In other instances, well-known features, such as tool layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

In accordance with at least some embodiments of the present invention, hydrazine is used as a source of nitrogen in the chemical vapor deposition of group III-nitride material layers. By using hydrazine, the temperatures typically associated with the deposition of such layers may be reduced. Using hydrazine as a nitrogen source may reduce the activation barrier for introducing nitrogen atoms to group III species, such as gallium (Ga), aluminum (Al), or indium (In). It may be the case that hydrazine as a complete species is not the reactive component in the formation. Rather, fragments of a once formed hydrazine molecule may in fact be responsible for reaction with a group III precursor. In either case, low temperature processes may be achieved by using hydrazine in the chemical vapor deposition process. In an embodiment, rather than delivering hydrazine to a facility wherein the deposition process is performed, the hydrazine is fabricated in-situ, as described in more detail below.

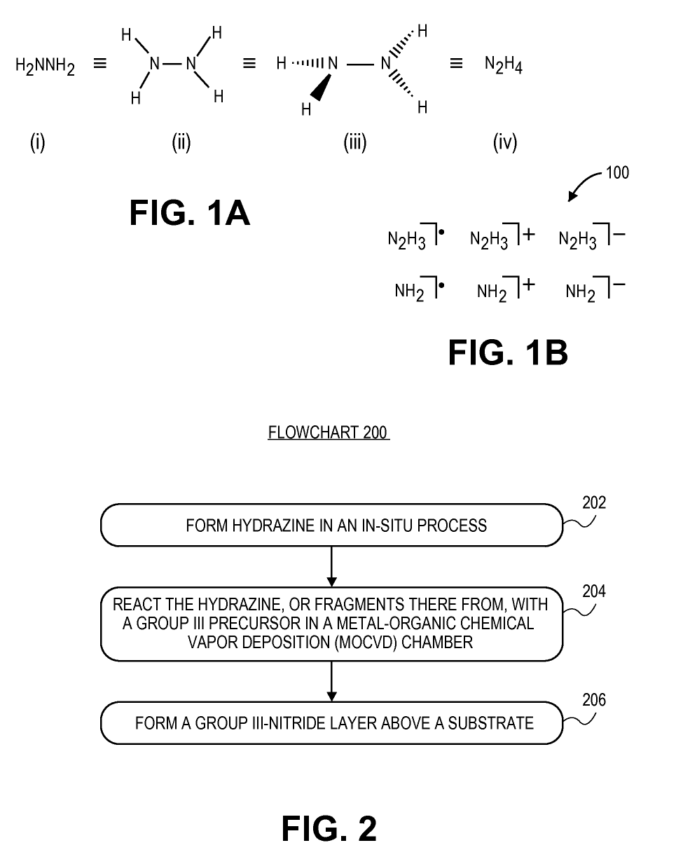

Hydrazine is an inorganic chemical compound with the formula N₂H₄. FIG. 1A illustrates different representations of the molecule hydrazine (N₂H₄). Referring to FIG. 1A, (i) represents a non-spatial formula for hydrazine without bonding depicted, (ii) represents a non-spatial formula for hydrazine with bonding depicted, (iii) represents a spatial formula for hydrazine with bonding depicted, and (iv) indicates that all representations are equivalent to N₂H₄ for hydrazine. Hydrazine is a colorless, flammable liquid with an ammonia-like odor and is derived from the same industrial chemistry processes that manufacture ammonia. However, hydrazine has physical properties that are closer to those of water. Hydrazine is highly toxic and dangerously unstable, and is usually handled while in solution for safety reasons. Hydrazine is mainly used as a foaming agent in preparing polymer foams, but significant applications also include its uses as a precursor to polymerization catalysts and pharmaceuticals. Additionally, hydrazine is used in various rocket fuels and to prepare the gas precursors used in air bags.

Hydrazine is produced in the Olin Raschig process from sodium hypochlorite and ammonia. This method relies on the reaction of chloramine with ammonia. Another route of hydrazine synthesis involves oxidation of urea with sodium hypochlorite. Hydrazine can be synthesized from ammonia and hydrogen peroxide in the Pechiney-Ugine-Kuhlmann process. In the Atofina-PCUK cycle, hydrazine is produced in several steps from acetone, ammonia, and hydrogen peroxide. Acetone and ammonia first react to give the imine followed by oxidation with hydrogen peroxide to the oxaziridine, a three-membered ring containing carbon, oxygen, and nitrogen, followed by ammonolysis to the hydrazone, a process that couples two nitrogen atoms. This hydrazone reacts with one more equivalent of acetone, and the resulting acetone azine is hydrolyzed to give hydrazine, regenerating acetone. Unlike the Raschig process, this process does not produce salt. Hydrazine can also be produced via the so-called ketazine and peroxide processes.

Thus, given the dangers in handling pre-fabricated hydrazine, as well as the complexity of processes used to generate hydrazine for storage and handling purposes, in accordance with an embodiment of the present invention, hydrazine is generated in real time for use in a MOCVD process to form group III-nitride material layers. In an embodiment, using in-situ generated hydrazine to deliver nitrogen in an MOCVD process lowers the activation energy barrier for the introduction of nitrogen to group III species as compared to process that use either NH₃ or N₂ (with or without trace amounts of H₂) under conditions that are not suitable for considerable hydrazine formation. For example, in one embodiment, a plasma based on N₂/H₂ or NH₃ is used under conditions suitable to form a substantial amount of hydrazine, e.g., an amount required to provide the primary source of nitrogen in a reaction with a group III precursor. In other embodiments, in-situ hydrazine is formed by a catalysis process or by ultra-violet irradiation of N₂ and H₂ in combination.

Embodiments herein may be distinguished from other nitrogen-based plasmas, e.g., an ammonia/hydrogen plasma, where the presence of too great a concentration of hydrogen relative to the nitrogen source may hinder the formation of hydrazine as a low temperature driving intermediate. For example, in a specific embodiment described below, for the formation of InGaN, as the temperature is increased above 650 degrees Celsius, the N/group III ratio is appropriately decreased so the excess hydrogen partial pressure does not inhibit indium incorporation into a fabricated ternary group III-nitride film. Embodiments herein may also be distinguished from other nitrogen-based plasmas, e.g., a nitrogen (N2)/hydrogen plasma, where the presence of too small a concentration of hydrogen relative to the nitrogen source may hinder the formation of hydrazine as a low temperature driving intermediate.

In at least some embodiments, using in-situ generated hydrazine provides a low energy pathway to group III-nitride formation. Thus, in some embodiments, a relatively low temperature deposition process is used. It is to be understood that the hydrazine may break-down prior to actual reaction with a group III precursor and, as such, a fragment of hydrazine is responsible for actual nitrogen delivery. FIG. 1B illustrates a collection 100 of possible radical, cation, and anion fragments of hydrazine suitable for delivery of nitrogen to a group III precursor in the formation of a group III-nitride material layer, in accordance with an embodiment of the present invention.

Described herein are methods of fabricating group III-nitride materials. In one embodiment, a method includes forming hydrazine in an in-situ process. The hydrazine, or fragments there from, is reacted with a group III precursor in a metal-organic chemical vapor deposition (MOCVD) chamber. From the reacting, a group III-nitride layer is formed above a substrate.

Also disclosed herein are process tools for fabricating group III-nitride materials. In one embodiment, a process tool includes means to form hydrazine in an in-situ process. An MOCVD chamber is included for reacting the hydrazine, or fragments there from, with a group III precursor to form a group III-nitride layer above a substrate.

Light-emitting diodes (LEDs) and related devices may be fabricated from layers of, e.g., group III-V films, especially group III-nitride films. Some embodiments of the present invention relate to forming gallium nitride (GaN) layers in a dedicated chamber of a fabrication tool, such as in a dedicated metal-organic chemical vapor deposition (MOCVD) chamber. In some embodiments of the present invention, GaN is a binary GaN film, but in other embodiments, GaN is a ternary film (e.g., InGaN, AlGaN) or is a quaternary film (e.g., InAlGaN). In at least some embodiments, the group III-nitride material layers are formed epitaxially. They may be formed directly on a substrate or on a buffers layer disposed on a substrate.

In an aspect of the present invention, a group III-nitride material layer is formed by a MOCVD process using in-situ generated hydrazine or fragments there from. For example, FIG. 2 is a Flowchart 200 representing operations in a method of fabricating a group III-nitride material, in accordance with an embodiment of the present invention.

Referring to operation 202 of Flowchart 200, a method includes forming hydrazine in an in-situ process.

In an embodiment, forming the hydrazine in the in-situ process includes forming the hydrazine in a plasma process. In one such embodiment, forming the hydrazine in the plasma process comprises performing the plasma process in the MOCVD chamber. In a specific such embodiment, the plasma process is based on ammonia (NH₃) gas. In another specific such embodiment, the plasma process is based on a combination of hydrogen (H₂) gas and nitrogen (N₂) gas. In another one such embodiment, forming the hydrazine in the plasma process includes performing the plasma process remote to the MOCVD chamber. In a specific such embodiment, the plasma process is based on ammonia (NH₃) gas. In another specific such embodiment, the plasma process is based on a combination of hydrogen (H₂) gas and nitrogen (N₂) gas.

The specific conditions suitable for high concentration hydrazine formation differ from conventional MOCVD conditions. For example, in an embodiment, a plasma based on a combination of H₂ and N₂ gas flows is used to produce an amount of hydrazine sufficient to provide hydrazine as the primary nitrogen delivery source. This approach differs from conventional N₂-based plasmas which may use a small amount of H₂ gas as a minor catalyst or scrubber gas. With respect to ammonia-based plasma conditions for high concentration hydrazine formation, examples of such conditions are provided below.

In another embodiment, forming the hydrazine in the in-situ process includes flowing a combination of hydrogen (H₂) gas and nitrogen (N₂) gas over a solid metal catalyst. In another embodiment, forming the hydrazine in the in-situ process includes exposing a combination of hydrogen (H₂) gas and nitrogen (N₂) to ultra-violet (UV) light. In another embodiment, forming the hydrazine in the in-situ process includes exposing ammonia or a combination of hydrogen (H₂) gas and nitrogen (N₂) to a laser.

Referring to operation 204 of Flowchart 200, the method further includes reacting the hydrazine, or fragments there from, with a group III precursor in a metal-organic chemical vapor deposition (MOCVD) chamber.

Referring to operation 206 of Flowchart 200, the method further includes forming, from the reacting, a group III-nitride layer above a substrate. In an embodiment, the group III precursor is a gallium-based precursor, and the group III-nitride layer is a gallium nitride layer. In another embodiment, the group III precursor includes both a gallium-based precursor and an indium-based precursor, and the group III-nitride layer is an indium gallium nitride layer.

Known ammonia-based plasma processes use high temperatures and very high pressures of ammonia to supply adequate active nitrogen for the growing, e.g., a GaN film. In accordance with an embodiment of the present invention a remote plasma based on ammonia is used under conditions suitable to generate sufficient quantities of hydrazine to be the primary nitrogen delivery source for formation of a group III-nitride layer. For example, in one embodiment, a remote plasma assisted MOCVD process is used for GaN growth on silicon.

Using remote plasma activation of the nitrogen source, the high pressure and high temperature requirements are removed. In this way, single crystal GaN can be grown on a variety of substrate materials at low flows and pressures of ammonia, and also at low temperatures. This approach enhances the chamber capability, as well as provides lower materials cost (e.g., through lower ammonia flow), and benefits due to lower cost substrate alternatives. Single crystal GaN growth has been demonstrated on sapphire, AlN, LiAlO, silicon and SiC substrates at low temperatures (570-720 degrees Celsius) and low pressures (2-12 Torr) and at low trimethyl gallium (TMGa) to ammonia ratios (down to 1:25).

For fabrication of an LED, in an embodiment, the substrates are disposed of entirely after the devices have been formed. Sapphire substrates can be expensive and currently are not available in the larger sizes (8″ and 12″ diameters for example). Silicon wafers of very high quality are very easy and inexpensive to obtain from the semiconductor industry. GaN on silicon deposition, however, has proven to exhibit some limitations in the past. There are, e.g., lattice mismatch issues which may prevent epitaxial growth. There may also be coefficient of thermal expansion (CTE) mismatch issues, which may induce stress and possible cracking of the films if the processing temperature is too high. Finally, there may be the issue of gallium melt-back etching when gallium contacts silicon at high temperatures. There is therefore a great desire to be able to grow single crystal GaN films on low cost substrates such as silicon. Such may be achieved, in an embodiment, using the low temperature processing made possible by the use of the remote plasma assisted MOCVD process which generates in-situ hydrazine.

In accordance with another embodiment of the present invention an in-situ or a remote plasma based on ammonia is used under conditions suitable to generate sufficient quantities of hydrazine to be the primary nitrogen delivery source for formation of a group III-nitride layer. For example, a plasma assisted MOCVD process is used to form a GaN buffer layer deposited on sapphire and other substrates.

Sapphire substrates are commonly used but can have a lattice mismatch to a GaN layer grown thereon. Conventionally, a buffer layer is grown on the substrate to transition the Al₂O₃ of the substrate to GaN, through the use of layers such as AlN, sapphire nitridation, low temperature GaN, etc. In an embodiment, using plasma activation of the nitrogen source to generate hydrazine in-situ, high pressure and high temperature requirements may be removed. In this way, single crystal GaN can be grown on a variety of substrate materials at low flows and pressures of ammonia, and also at low temperatures. For example, in certain embodiments, single crystal GaN growth has been demonstrated directly on sapphire, AlN, LiAlO, silicon and SiC substrates at low temperatures (570-720 degrees Celsius) and low pressures (2-12 Torr) and at low trimethyl gallium (TMGa) to ammonia ratios (down to 1:25).

In accordance with another embodiment of the present invention an in-situ or a remote plasma based on ammonia is used under conditions suitable to generate sufficient quantities of hydrazine to be the primary nitrogen delivery source for formation of a ternary group III-nitride layer. For example, in an embodiment, a plasma assisted MOCVD process is used to form an InGaN material layer.

High indium (In) incorporation by plasma assisted low temperature MOCVD of InGaN is described below. Conventionally, there are several growth challenges that make it difficult to produce high quality single crystal InGaN films by MOCVD. Of the group III-nitrides, InN is by far the most difficult to grow due to its high equilibrium nitrogen vapor pressure. The high equilibrium vapor pressure of InN limits the deposition temperature to less than 650 degrees Celsius to prevent film decomposition. The source materials typically used in MOCVD growth of InN are trimethyl indium (TMIn) and NH₃. At these lower deposition temperatures, the extent of ammonia decomposition is very low, less than 0.1% at 500 degrees Celsius. Due to this lack of reactive nitrogen, indium droplets can form on the surface, therefore the inlet N/In ratio must be kept sufficiently high (˜50,000) to avoid formation of indium droplets. High inlet N/In ratios are only required for growth at temperature ≦600 degrees Celsius since ammonia decomposition occurs readily at higher temperature (≧650 degrees Celsius). The extent of decomposition of ammonia, however, significantly increases the H₂ partial pressure, which has been shown to retard the InN growth rate. This is also the reason that a nitrogen carrier gas may be preferred over a hydrogen carrier gas.

In consideration of the above growth challenges, there may be a narrow temperature window (approximately 400-650 degrees Celsius) for successful growth of InN and InGaN by MOCVD. The growth temperature may be the most important parameter for controlling film properties such as crystalline quality, growth rate, surface morphology and carrier concentration. Additionally, the vapor pressure difference between InN and GaN may pose another problem that affects high quality growth of InₓGa₁₋ₓN alloys. Thus, there are several growth challenges that must be overcome for successful growth of Inₓ Ga₁₋ₓN alloys. Perhaps most challenging is that phase separation can occur in the alloy due to an 11% lattice mismatch between InN and GaN. From analysis of the solid phase miscibility gap in the InₓGa₁₋ₓN system, it was determined the maximum equilibrium incorporation of In into GaN (or Ga into InN) may be less than 6% at a typical deposition temperature of 800 degrees Celsius. InₓGa₁₋ₓN alloys may be theoretically unstable or metastable over a large compositional range at typical growth temperatures.

Indium incorporation may be affected by deposition temperature when using TMIn and TMGa. The distribution coefficient of indium between the vapor and sold phases may be considerably greater than unity at 800 degrees Celsius because of the large difference in decomposition pressure at elevated temperature along with near equilibrium conditions at the growth interface at this higher temperature. At the lower temperature of 500 degrees Celsius, the distribution coefficient may be close to unity suggesting non-equilibrium (reaction limited) conditions. Furthermore, at 800 degrees Celsius, control of the composition may become difficult for intermediate compositions given the rapid change in solid composition with the vapor phase.

In accordance with an embodiment of the present invention, an N/group III inlet ratio is selected to correspond with a specified deposition temperature. In one embodiment, ammonia decomposition efficiency, e.g. to hydrazine, is used to determine the actual N/group III ratio. However, it may be difficult to know the exact NH₃ decomposition efficiency since the value relies heavily on the reactor design as well as temperature. For this reason, in an embodiment, the inlet flow ratio of NH₃/(TMIn+TMGa) is commonly listed as the N/group III ratio for MOCVD growth. When the deposition temperature is low (≦600 degrees Celsius), the inlet N/group III ratio is selected to be sufficiently high to maintain effective levels of active nitrogen (e.g., in the form of hydrazine or fragments there from) and avoid indium droplet formation. As the temperature is increased above 650 degrees Celsius, the N/group III ratio is appropriately decreased so the excess hydrogen partial pressure does not inhibit indium incorporation into the film. Growth of Inₓ Ga₁₋ₓN alloys (especially for In-rich compositions) may otherwise be difficult due to the narrow growth regimes of InN coupled with phase separation and vapor pressure differences that occur with the addition of gallium to InN.

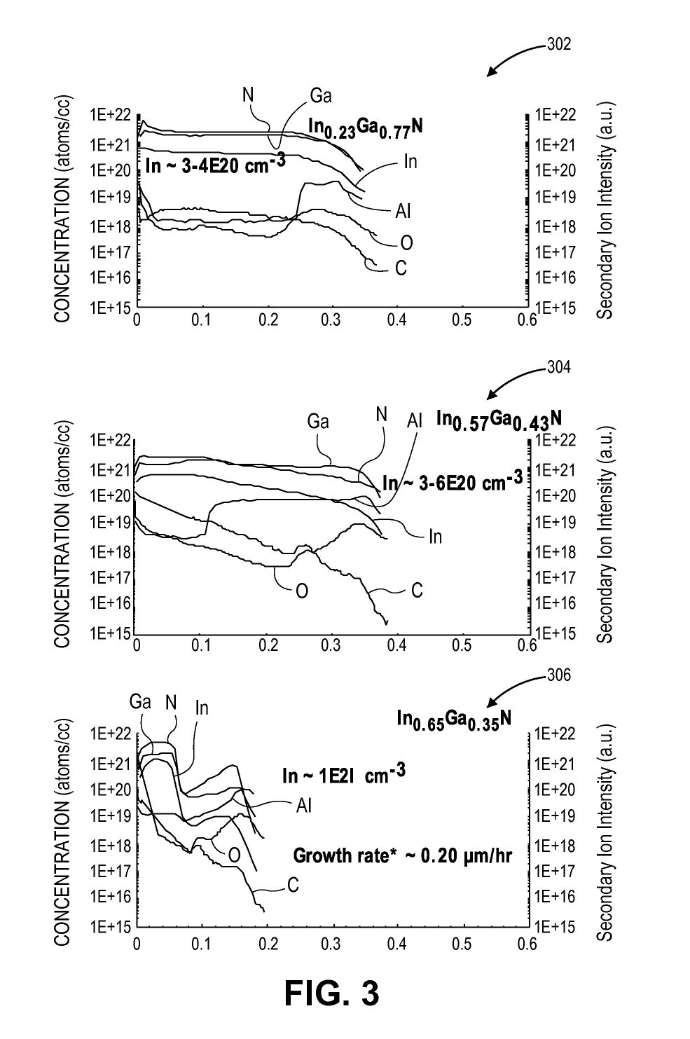

In accordance with embodiments of the present invention, modified MOCVD deposition techniques, such as plasma or laser assisted MOCVD are suitable to produce more reactive nitrogen at low growth temperatures (e.g., through a hydrazine intermediate), thus avoiding some of the pitfalls of conventional MOCVD. In an embodiment, a low temperature approach with increased active N available by plasma assisted MOCVD process is used to suppress InGaN phase separation. For example, FIG. 3 includes three SIMS depth profile plots 302, 304, and 306 for fabricated InGaN at different growth temperatures, in accordance with an embodiment of the present invention. Referring to plot 302, In_{0.23}Ga_{0.77}N is formed at a growth rate of approximately 0.72 microns/hour at a temperature of 670 degrees Celsius. Referring to plot 304, In_{0.57}Ga_{0.43}N is formed at a growth rate of approximately 0.60 microns/hour at a temperature of 620 degrees Celsius. Referring to plot 306, In_{0.65}Ga_{0.35}N is formed at a growth rate of approximately 0.20 microns/hour at a temperature of 570 degrees Celsius.

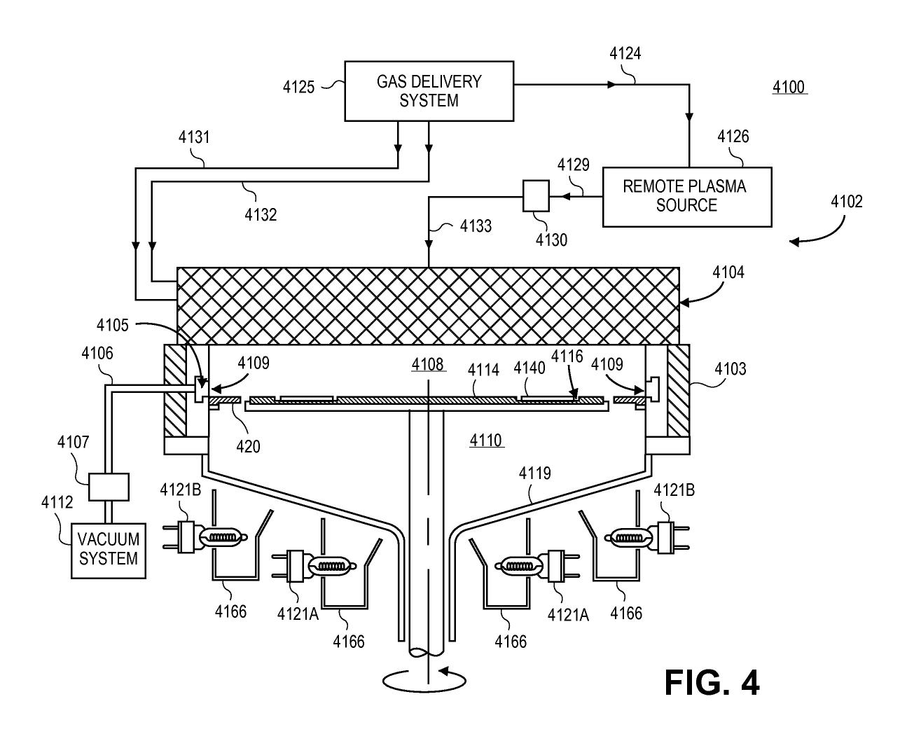

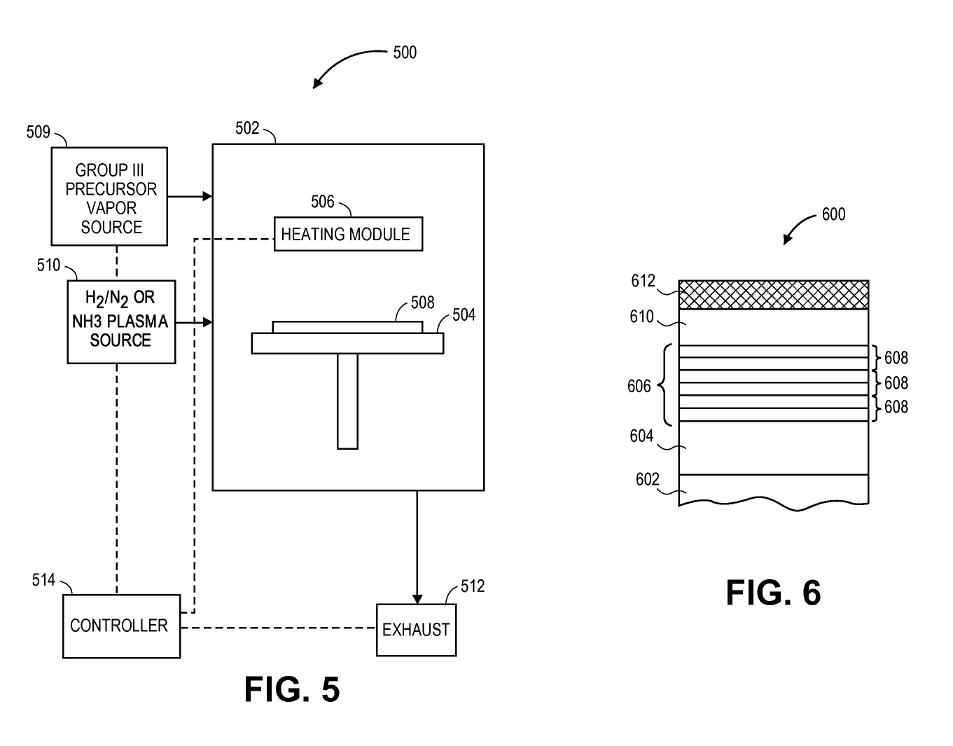

In another aspect of the present invention, as exemplified in more detail in association with FIGS. 4 and 5 below, a process tool for fabricating a group III-nitride material is provided.

In an embodiment, such a process tool includes features suitable to form hydrazine in an in-situ process. The process tool also includes a MOCVD chamber for reacting the hydrazine, or fragments there from, with a group III precursor to form a group III-nitride layer above a substrate.

In an embodiment, the features suitable to form hydrazine in the in-situ process include an apparatus to form the hydrazine in a plasma process. In one such embodiment, the apparatus is located in the MOCVD chamber. In another such embodiment, the apparatus is located remote to the MOCVD chamber. In another such embodiment, the apparatus is configured to generate a plasma based on ammonia (NH₃) gas. In another such embodiment, the apparatus is configured to generate a plasma based on a combination of hydrogen (H₂) gas and nitrogen (N₂) gas.

In an embodiment, the features suitable to form hydrazine in the in-situ process include an apparatus for forming the hydrazine by flowing a combination of hydrogen (H₂) gas and nitrogen (N₂) gas over a solid metal catalyst. In another embodiment, the features suitable to form hydrazine in the in-situ process include an apparatus for exposing a combination of hydrogen (H₂) gas and nitrogen (N₂) to ultra-violet (UV) light. In another embodiment, the features suitable to form hydrazine in the in-situ process include an apparatus for exposing ammonia or a combination of hydrogen (H₂) gas and nitrogen (N₂) to a laser.

An example of an MOCVD deposition chamber which may be utilized for fabrication of group III-nitride materials using in-situ generated hydrazine or fragments there from, in accordance with embodiments of the present invention, is illustrated and described with respect to FIG. 4.

FIG. 4 is a schematic cross-sectional view of an MOCVD chamber according to an embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 4100 shown in FIG. 4 comprises a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrate 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104 may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may comprise resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as films, for example, on substrates 4140.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

FIG. 5 illustrates a system suitable for fabrication of group III-nitride materials using in-situ generated hydrazine or fragments there from, in accordance with an embodiment of the present invention.

Referring to FIG. 5, the system 500 may include a deposition chamber 502 that includes a substrate support 504 and a heating module 506. The substrate support 504 may be adapted to support a substrate 508 during film formation within the chamber 502, and the heating module 506 may be adapted to heat the substrate 508 during film formation within the deposition chamber 502. More than one heating module, and/or other heating module locations may be used. The heating module 506 may include, for example, a lamp array or any other suitable heating source and/or element.

The system 500 may also include a group III, e.g., gallium, vapor source 509, a N₂/H₂ or NH₃ plasma source 510, and an exhaust system 512 coupled to the deposition chamber 502. The system 500 may also include a controller 514 coupled to the deposition chamber 502, the group III vapor source 509, the N₂/H₂ or NH₃ plasma source 510, and/or the exhaust system 512. The exhaust system 512 may include any suitable system for exhausting waste gasses, reaction products, or the like from the chamber 502, and may include one or more vacuum pumps. The N₂/H₂ or NH₃ plasma source 510 may, in accordance with an embodiment of the present invention, be suitable to provide a substantial amount of hydrazine, or fragments there from, for reaction with vapor for the group III vapor source 509. The N₂/H₂ or NH₃ plasma source 510 may be used to generate a plasma in the deposition chamber or remotely and introduced into the deposition chamber.

The controller 514 may include one or more microprocessors and/or microcontrollers, dedicated hardware, a combination the same, etc., that may be employed to control operation of the deposition chamber 502, the group III vapor source 509, the N₂/H₂ or NH₃ plasma source 510, and/or the exhaust system 512. In at least one embodiment, the controller 514 may be adapted to employ computer program code for controlling operation of the system 500. For example, the controller 514 may perform or otherwise initiate one or more of the operations of any of the methods/processes described herein, including the method described in association with Flowchart 200. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

Group III precursor vapor may be created by placing an elemental group III species into a vessel, such as a crucible, and heating the vessel to melt the elemental group III species. The vessel may be heated to a temperature of from about 100 degrees Celsius to about 250 degrees Celsius. In some embodiments, nitrogen gas may be passed over the vessel containing the molten elemental group III species at a pressure of about 1 Torr and pumped to the process chamber. The nitrogen may be flowed at a rate of about 200 standard cubic centimeters per minute (sccm). The group III precursor vapor may be drawn into the process chamber by a vacuum. In an alternative embodiment, the substrate may be exposed to the group III precursor vapor, the N₂/H₂ or NH₃ based plasma and one or more of hydrogen and hydrogen chloride. The hydrogen and/or the hydrogen chloride may increase the rate of deposition. In another embodiment of the present invention, a group III-nitride film may be deposited on a substrate using a group III sesquichloride precursor and/or a group III hydride precursor.

A group III-nitride layer fabricated from hydrazine generated in-situ may be used in the fabrication of a light-emitting diode device. For example, FIG. 6 illustrates a cross-sectional view of a gallium nitride (GaN)-based light-emitting diode (LED), in accordance with an embodiment of the present invention.

Referring to FIG. 6, a GaN-based LED 600 includes an n-type GaN template 604 (e.g., n-type GaN, n-type InGaN, n-type AlGaN, n-type InAlGaN) on a substrate 602 (e.g., planar sapphire substrate, patterned sapphire substrate (PSS), silicon substrate, silicon carbide substrate). The GaN-based LED 600 also includes a multiple quantum well (MQW), or active region, structure or film stack 606 on or above the n-type GaN template 604 (e.g., an MQW composed of one or a plurality of field pairs of InGaN well/GaN barrier material layers 608, as depicted in FIG. 6). The GaN-based LED 600 also includes a p-type GaN (p-GaN) layer or film stack 610 on or above the MQW 606, and a metal contact or ITO layer 612 on the p-GaN layer.

It is to be understood that embodiments of the present invention are not limited to formation of layers on patterned sapphire substrates. Other embodiments may include the use of any suitable patterned single crystalline substrate upon which a group III nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate. In other embodiments, the approaches herein are used to provide a group III-material layer directly on a silicon substrate.

In some embodiments, growth of a gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (Θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to n-GaN as a group III-V layer formed on a patterned substrate, such as described in association with FIG. 6. For example, other embodiments may include any group III-nitride epitaxial film that can be suitably deposited by MOCVD, or the like, using in-situ generated hydrazine or fragments there from. The group III-nitride film may be a binary, ternary, or quaternary compound semiconductor film formed from a group III element or elements selected from gallium, indium and aluminum and nitrogen. That is, the group III-nitride crystalline film can be any solid solution or alloy of one or more Group III element and nitrogen, such as but not limited to GaN, AlN, InN, AlGaN, InGaN, InAlN, and InGaAlN.

However, in a specific embodiment, the group III-nitride film is an n-type gallium nitride (GaN) film. The Group III-Nitride film can have a thickness between 2-500 microns and is typically formed between 2-15 microns. In an embodiment of the present invention, the group III-nitride film has a thickness of at least 3.0 microns to sufficiently suppress threading dislocations. Additionally, as described above, the group III-nitride film can be doped. The group III-nitride film can be p-typed doped using any p-type dopant such as but not limited Mg, Be, Ca, Sr, or any Group I or Group II element have two valence electrons. The group III-nitride film can be p-type doped to a conductivity level of between 1×10¹⁶ to 1×10²⁰ atoms/cm³.

It is to be understood that on the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by an MOCVD process using hydrazine generated in-situ, such as but not limited to field-effect transistor (FET) devices. In such embodiments, there may not be a need for a p-type material on top of a structure of layers. Instead, an n-type or un-doped material may be used in place of the p-type layer.

Thus, MOCVD fabrication of group III-nitride materials using in-situ generated hydrazine or fragments there from has been disclosed. In accordance with an embodiment of the present invention, a method of fabricating a group III-nitride material includes forming hydrazine in an in-situ process. The method also includes reacting the hydrazine, or fragments there from, with a group III precursor in an MOCVD chamber. The method also includes forming, from the reacting, a group III-nitride layer above a substrate. In one embodiment, forming the hydrazine in the in-situ process includes forming the hydrazine in a plasma process. In one embodiment, forming the hydrazine in the in-situ process includes flowing a combination of hydrogen (H₂) gas and nitrogen (N₂) gas over a solid metal catalyst. In one embodiment, forming the hydrazine in the in-situ process comprises exposing a combination of hydrogen (H₂) gas and nitrogen (N₂) to ultra-violet (UV) light.

What is claimed is:

1. A method of fabricating a group III-nitride material, the method comprising:
forming hydrazine in an in-situ process;
reacting the hydrazine, or fragments there from, with a group III precursor in a metal-organic chemical vapor deposition (MOCVD) chamber; and
forming, from the reacting, a group III-nitride layer above a substrate.

2. The method of claim 1, wherein forming the hydrazine in the in-situ process comprises forming the hydrazine in a plasma process.

3. The method of claim 2, wherein forming the hydrazine in the plasma process comprises performing the plasma process in the MOCVD chamber.

4. The method of claim 3, wherein the plasma process is based on ammonia (NH₃) gas.

5. The method of claim 3, wherein the plasma process is based on a combination of hydrogen (H₂) gas and nitrogen (N₂) gas.

6. The method of claim 2, wherein forming the hydrazine in the plasma process comprises performing the plasma process remote to the MOCVD chamber.

7. The method of claim 6, wherein the plasma process is based on ammonia (NH₃) gas.

8. The method of claim 6, wherein the plasma process is based on a combination of hydrogen (H₂) gas and nitrogen (N₂) gas.

9. The method of claim 1, wherein forming the hydrazine in the in-situ process comprises flowing a combination of hydrogen (H₂) gas and nitrogen (N₂) gas over a solid metal catalyst.

10. The method of claim 1, wherein forming the hydrazine in the in-situ process comprises exposing a combination of hydrogen (H₂) gas and nitrogen (N₂) to ultra-violet (UV) light.

11. The method of claim 1, wherein forming the hydrazine in the in-situ process comprises exposing ammonia or a combination of hydrogen (H₂) gas and nitrogen (N₂) to a laser.

12. The method of claim 1, wherein the group III precursor is a gallium-based precursor, and the group III-nitride layer is a gallium nitride layer.

13. The method of claim 1, wherein the group III precursor comprises both a gallium-based precursor and an indium-based precursor, and the group III-nitride layer is an indium gallium nitride layer.

14. A process tool for fabricating a group III-nitride material, the process tool comprising:
means to form hydrazine in an in-situ process; and
a metal-organic chemical vapor deposition (MOCVD) chamber for reacting the hydrazine, or fragments there from, with a group III precursor.

15. The process tool of claim 14, wherein the means to form hydrazine in the in-situ process comprises means to form the hydrazine in a plasma process.

16. The process tool of claim 15, wherein the means to form the hydrazine in the plasma process is located in the MOCVD chamber.

17. The process tool of claim 15, wherein the means to form the hydrazine in the plasma process is located remote to the MOCVD chamber.

18. The process tool of claim 15, wherein the means to form the hydrazine in the plasma process includes means to generate a plasma based on ammonia (NH₃) gas.

19. The process tool of claim 15, wherein the means to form the hydrazine in the plasma process includes means to generate a plasma based on a combination of hydrogen (H₂) gas and nitrogen (N₂) gas.

20. The process tool of claim 14, wherein the means to form hydrazine in the in-situ process comprises means to form the hydrazine by flowing a combination of hydrogen (H₂) gas and nitrogen (N₂) gas over a solid metal catalyst.

21. The process tool of claim 14, wherein the means to form hydrazine in the in-situ process comprises means to form the hydrazine by exposing a combination of hydrogen (H₂) gas and nitrogen (N₂) to ultra-violet (UV) light.

22. The process tool of claim 14, wherein the means to form hydrazine in the in-situ process comprises means to form the hydrazine by exposing a ammonia or combination of hydrogen (H₂) gas and nitrogen (N₂) to a laser.

23. The process tool of claim 14, wherein reacting the hydrazine, or fragments there from, with the group III precursor is for forming a group III-nitride layer above a substrate.
